(19) United States
(12) Patent Application Publication
(10) Pub. No.: US 2005/0176193 A1
(43) Pub. Date: Aug. 11, 2005

(54) Method of forming a gate of a semiconductor device

(76) Inventors: Tae-Woong Kang, Suwon-si (KR); Jong-Hyon Ahn, Suwon-si (KR)

Correspondence Address: MILLS & ONELLO LLP, ELEVEN BEACON STREET, SUITE 605, BOSTON, MA, 02108, US

(21) Appl. No.: 11/036,235

(22) Filed: Jan. 14, 2005

(30) Foreign Application Priority Data
Jan. 15, 2004 (KR) 04-2945

(51) Int. Cl. H01L 21/336; H01L 21/8234; H01L 21/4763; H01L 21/3205

(52) U.S. Cl. 438/197; 438/585

(57) ABSTRACT

In a method of forming a gate of a semiconductor device, a gate insulating layer and a polysilicon layer are successively formed on a substrate that is partitioned into a field region and an active region. A hard mask is formed on the polysilicon layer. The hard mask overlaps with the active region and has a spacer pattern that partially extends into the field region. The polysilicon layer is partially etched using the hard mask as an etching mask to form the gate. The gate overlaps with the active region and has an end portion positioned in the field region. The end portion has a width at least as large as a thickness of the spacer pattern.

### CROSS REFERENCE TO RELATED APPLICATION

This application claims priority under 35 USC § 119 to Korean Patent Application No. 2004-2945, filed on Jan. 15, 2004, the contents of which are herein incorporated by reference in their entirety.

### BACKGROUND OF THE INVENTION

1. Field of the Invention

The present invention relates to a method of forming a gate of a semiconductor device. More particularly, the present invention relates to a method of forming a gate of an SRAM device that has a minute gate length and a separate pattern.

2. Description of the Related Art

Generally, volatile semiconductor memory devices can be categorized into a dynamic random access memory (DRAM) device and a static random access memory (SRAM) device in accordance with memory type. The SRAM device offers the benefits of rapid speed, low power consumption and a relatively simple structure. For these, and other, reasons, the SRAM device is popular in the semiconductor memory field. In addition, while information stored in the DRAM device needs to be periodically refreshed, a periodic refresh of information stored in the SRAM device is not necessary.

A typical SRAM device includes two pull-down elements, two pass elements and two pull-up elements. SRAM devices can be generally classified as a full CMOS type, a high load resistor (HLR) type and a thin film transistor (TFT) type in accordance with the configuration of the pull-up elements. A p-channel bulk MOSFET is used as the pull-up element in the full CMOS type. A polysilicon layer having a high resistance value is used as the pull-up element in the HLR type. A p-channel polysilicon TFT is used as the pull-up element in the TFT type. An SRAM device of the full CMOS type has a low standby current, and also operates with greater stability, as compared to an SRAM device of the other types.

FIG. 1 is a circuit illustrating a conventional full CMOS type SRAM cell. Referring to FIG. 1, a conventional SRAM cell includes first and second pass transistors Q1 and Q2 for electrically connecting first and second bit lines B/L and /(B/L) to first and second memory cell nodes Nd1 and Nd2, respectively, a PMOS type pull-up transistor Q5 electrically connected between the first memory cell node Nd1 and a positive supply voltage Vcc, and an NMOS type pull-down transistor Q3 electrically connected between the first memory cell node Nd1 and a negative supply voltage Vss. The PMOS type pull-up transistor Q5 and the NMOS type pull-down transistor Q3 are controlled by a signal output by the second memory cell node Nd2 to thereby provide the positive supply voltage Vdd or the negative supply voltage Vss to the first memory cell node Nd1.

The conventional SRAM cell further includes a PMOS type pull-up transistor Q6 electrically connected between the positive supply voltage Vdd and the second memory cell node Nd2, and an NMOS type pull-down transistor Q4 electrically connected between the second memory node Nd2 and the negative supply voltage Vss. The PMOS type pull-up transistor Q6 and the NMOS type pull-down transistor Q4 are controlled by a signal output by the first memory cell node Nd1 to thereby provide the positive supply voltage Vdd or the negative supply voltage Vss to the second memory cell node Nd2.

The first pass transistor Q1, the NMOS type pull-down transistor Q3 and the PMOS pull-up transistor Q5 are interconnected at the first memory cell node Nd1. The second pass transistor Q2, the NMOS type pull-down transistor Q4 and the PMOS pull-up transistor Q6 are interconnected at the second memory cell node Nd2.

The full CMOS type SRAM cell includes the NMOS type transistors Q1, Q2, Q3 and Q4, and the PMOS type transistors Q5 and Q6. The NMOS and PMOS type transistors are disposed adjacent to each other in a cell. A transistor having linear gates that are employed in the DRAM or a non-volatile memory (NVM) may not be embodied in the SRAM in which a plurality of transistors is required. Thus, the gates of the transistors in the SRAM are disposed as separate and divided patterns.

Here, an overlapped portion between the gate pattern and the active region functions as a transistor. Therefore, to prevent the effective length of the gate in operation from being reduced, the gate pattern and the active region are sufficiently overlapped with each other. When the gate pattern is thus formed using a typical etching process, an edge of the gate pattern may be formed in a rounded shape.

FIG. 2 is a plan view illustrating a conventional mis-aligned gate pattern. Referring to FIG. 2, gate patterns 12 are overlapped with linear active regions 10. The gate patterns 12 are laterally shifted to one side so that the area of the overlapped portion between the gate pattern 12 and the active region 10 is reduced (see A). Thus, the resulting channel region at the rounded edge of the gate pattern 12 becomes small, which, in turn, can cause the transistor to malfunction.

To suppress the malfunction of the transistor, the gate pattern 12 is formed to a length that sufficiently covers the active region so that the rounded edge of the gate pattern 12 does not overlap with the active region 10.

However, as SRAM devices become increasingly integrated, it is increasingly difficult to maintain an overlap margin between the gate pattern 12 and the active region 10. To ensure sufficient overlap margin in recent highly-integrated SRAM devices, the gate pattern is formed using a hard mask.

FIGS. 3A to 3D are perspective views illustrating a conventional method of forming a gate using a hard mask. Referring to FIG. 3A, a semiconductor substrate 50 is divided into an active region and a field region, or field insulator region 52. A gate insulating layer 54, a polysilicon layer 56 and a hard mask layer 58 are successively formed on the substrate 50.

Referring to FIG. 3B, the hard mask layer 58 is partially etched to form a first hard mask layer pattern 58a having an opening that partially exposes an area of the polysilicon 56 above the field region 52. The polysilicon layer 56 is partially exposed through the opening of the first hard mask layer pattern 58a.

Referring to FIG. 3C, a photoresist film is formed on the first hard mask layer pattern 58a and the exposed polysilicon layer 56. The photoresist film is exposed and developed using a developing solution to form a photoresist pattern 60. Here, the photoresist pattern 60 is disposed substantially perpendicular to the opening of the first hard mask layer pattern 58a.

Referring to FIG. 3D, the first hard mask layer pattern 58a is etched using the photoresist pattern 60 as an etching mask to form a second hard mask layer pattern 62 having a shape that corresponds to an independent gate pattern. The polysilicon layer 56 is etched using the second hard mask layer pattern 62 as an etching mask to form a gate pattern 56a. The second hard mask layer pattern 62 is then removed.

However, as shown in FIG. 2, in guaranteeing the overlap margin of the gate pattern that is formed using the conventional method, the photoresist pattern 60 or the opening of the first hard mask layer pattern 58a may be mis-aligned on the polysilicon layer 56. As a result, the active region is partially exposed through the gate pattern, which can cause the resulting transistor to malfunction.

### SUMMARY OF THE INVENTION

The present invention provides a method of forming a gate of a semiconductor device that has a sufficient overlap margin and a vertical profile at an edge of the gate.

In accordance with one aspect of the present invention, in a method of forming a gate of a semiconductor device, a gate insulating layer and a polysilicon layer are successively formed on a substrate that is partitioned into a field region and an active region. A hard mask is formed on the polysilicon layer. The hard mask overlaps with the active region and has a spacer pattern that partially extends into the field region. The polysilicon layer is partially etched using the hard mask as an etching mask to form the gate. The gate overlaps with the active region and has an end portion positioned in the field region. The end portion has a width at least as large as a thickness of the spacer pattern.

In one embodiment, forming the hard mask comprises: forming a dielectric layer on the polysilicon layer; patterning the dielectric layer to form a dielectric layer pattern having an opening selectively exposing the polysilicon layer in the field region; forming a spacer on an inner sidewall of the opening of the dielectric layer pattern; forming a photoresist pattern on the dielectric layer pattern having the spacer; and etching the dielectric layer pattern and the spacer using the photoresist pattern as an etching mask to form the hard mask.

In another embodiment, the spacer pattern comprises silicon nitride, silicon oxynitride or polysilicon. The hard mask comprises silicon nitride or silicon oxynitride.

In another embodiment, the active region and the field region extend in a first direction, and the gate extends in a second direction substantially perpendicular to the first direction.

In another embodiment, the polysilicon layer is etched using an etchant having an etching selectivity between the polysilicon layer and the gate insulating layer.

In another embodiment, the gate has a length of no more than about 100 nm.

In another aspect, the present invention is directed to a method of forming a gate of a semiconductor device. A gate insulating layer and a polysilicon layer are successively formed on a substrate that is partitioned into an active region and a field region, the active region and the field region extending in a first direction. A dielectric layer pattern is formed on the polysilicon layer, the dielectric layer pattern having an opening that selectively exposes a surface of the polysilicon layer in the field region. A spacer is formed on an inner sidewall of the opening of the dielectric pattern. The dielectric layer having the spacer is partially etched to form a hard mask on the polysilicon layer, the hard mask overlapping with the active region and the hard mask including a spacer pattern that partially extends into the field region. The polysilicon layer is partially etched using the hard mask as an etching mask to form the gate that overlaps with the active region and that has an end portion positioned on the field region. The end portion of the gate has a width at least as large as a thickness of the spacer pattern. The gate extends in a second direction.

In one embodiment, forming the spacer comprises: forming a spacer layer having a thickness of about 10 Å to about 150 Å on exposed surfaces of the dielectric layer pattern and the polysilicon layer; and etching the spacer layer to form the spacer.

In another embodiment, the spacer layer comprises silicon nitride, silicon oxynitride or polysilicon.

In another embodiment, the hard mask comprises silicon nitride or silicon oxynitride.

In another embodiment, forming the hard mask comprises: forming a photoresist pattern in the second direction on the dielectric layer pattern having the spacer; and etching the dielectric layer pattern and the spacer using the photoresist pattern as an etching mask to form the hard mask.

In another embodiment, the polysilicon layer is etched using an etchant having an etching selectivity between the polysilicon layer and the gate insulating layer.

In another embodiment, the first direction is substantially perpendicular to the second direction.

According to the present invention, the resulting distance between adjacent gates is relatively very short so that the active region is not exposed, even in the case where the gate is laterally shifted to one side due to misalignment of the photoresist pattern or the hard mask. As a result, the overlap margin between the gate and the active region is sufficiently guaranteed so that malfunction of a transistor caused by insufficient overlap margin is prevented.

### BRIEF DESCRIPTION OF THE DRAWINGS

The above and other features and advantages of the invention will become readily apparent by reference to the following detailed description when considered in conjunction with the accompanying drawings wherein:

FIG. 1 is a circuit diagram illustrating a conventional full CMOS type SRAM cell;

FIG. 2 is a plan view illustrating a conventional mis-aligned gate pattern;

FIGS. 3A to 3D are perspective views illustrating a conventional method of forming a gate of a semiconductor device;

FIG. 4 is a plan view illustrating a gate pattern of a full CMOS SRAM cell in accordance with a first embodiment of the present invention;

FIG. 5 is a cross sectional view taken along line I-I′ in FIG. 4;

FIGS. 6A to 6G are perspective views illustrating a method of forming the gate of the SRAM device in FIG. 4;

FIGS. 7A to 7G are plan views illustrating a method of forming the gate of the SRAM device in FIG. 4; and

FIGS. 8A to 8C are perspective views illustrating a method of forming a gate of an SRAM device in accordance with a second embodiment of the present invention.

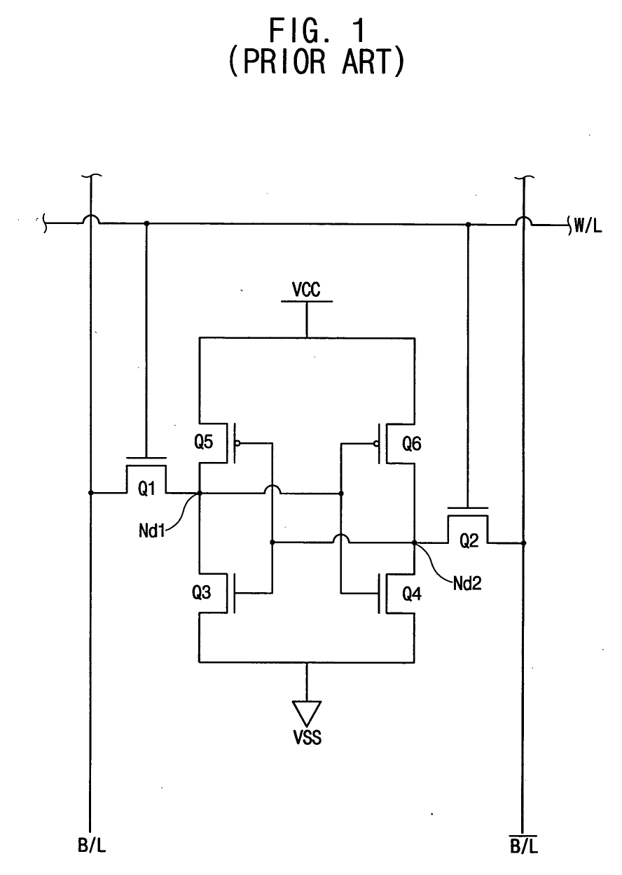

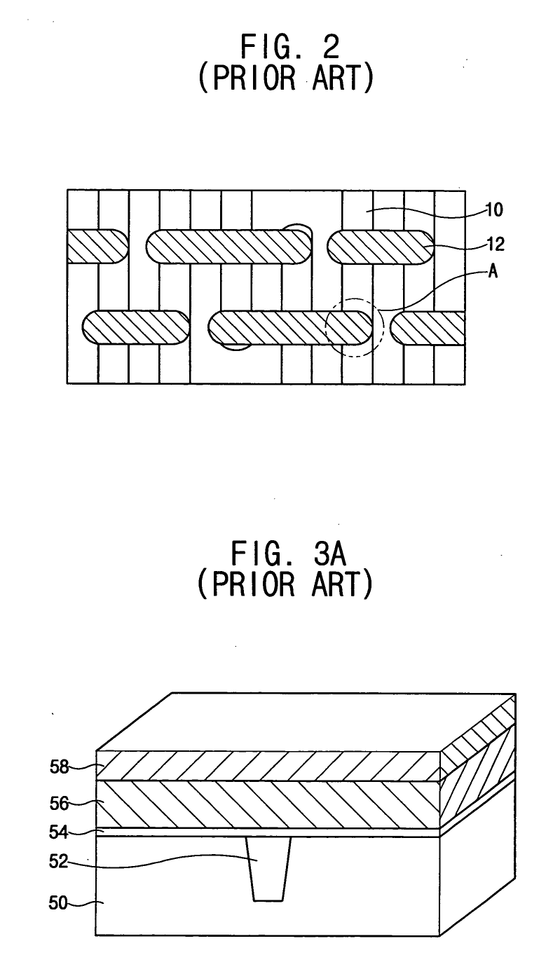

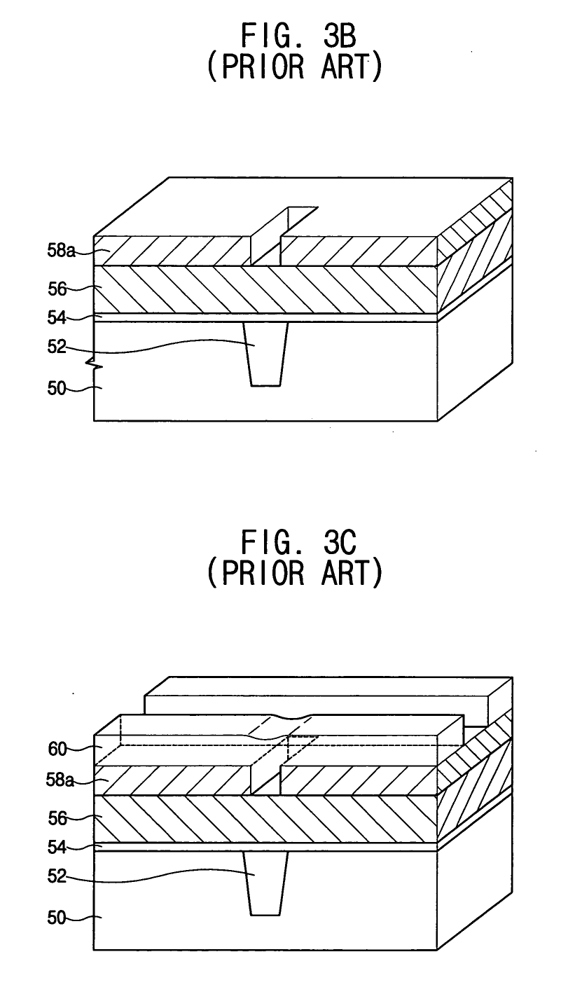

### DETAILED DESCRIPTION OF THE EMBODIMENTS

The present invention will now be described more fully with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it can be directly on the other element or intervening elements may also be present.

Hereinafter, a method of forming a gate of a semiconductor device of the present invention is illustrated in detail.

### Embodiment 1

A full CMOS type SRAM cell includes first and second pass transistors for electrically connecting first and second bit lines to first and second memory cell nodes, respectively, a first PMOS transistor electrically connected between the first memory cell node and a positive supply voltage, a first NMOS transistor electrically connected between the first memory cell node and a negative supply voltage, a second PMOS type transistor electrically connected between the positive supply voltage and the second memory cell node, and a second NMOS type transistor electrically connected between the second memory node and the negative supply voltage.

The NMOS and PMOS type transistors are disposed adjacent to each other in one cell. Thus, an active pattern is formed to provide regions in which the PMOS type transistor and the NMOS type transistor are formed in one cell. Also, a gate has a separate pattern shape.

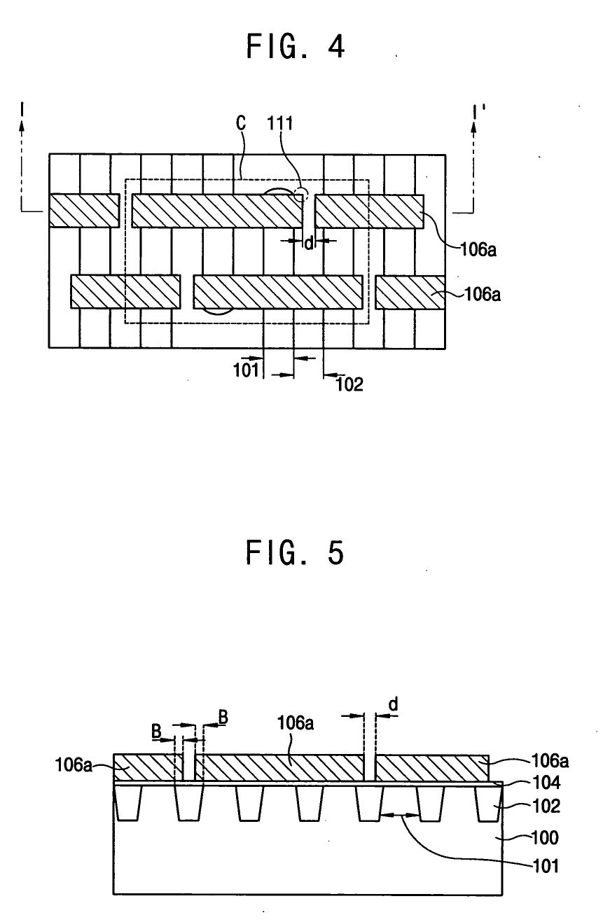

Referring to FIGS. 4 and 5, a plurality of chip dies is formed on a substrate. A cell array is provided in each chip. A plurality of unit cells is formed in the cell array. Here, a region in which one cell is formed is referred to as a unit cell region C.

A P-well region corresponding to a well region of the NMOS type transistor is formed in the unit cell region C. The P-well region is doped with P-type impurities. Also, an N-well region corresponding to a well region of the PMOS type transistor is formed in the unit cell region C. The N-well region is doped with N-type impurities. Linear active regions 101 are disposed in the N-type and the P-type well regions. Here, the linear active regions 101 may be fabricated using a shallow trench isolation (STI) process for forming field regions 102 between adjacent active regions.

A plurality of gate patterns 106a is formed on a gate insulating layer 104 in the active region 101. The gate patterns 106a are substantially perpendicular to the active region 101. The gate patterns 106a correspond to a polysilicon layer pattern that is formed by etching a polysilicon layer using a hard mask (not shown) including a spacer pattern.

Also, each gate pattern 106a serves as a gate electrode of the PMOS transistor or the NMOS transistor. The gate pattern 106a has a side edge, or sidewall, 111 having a substantially vertical profile. Thus, the distance d between the gate patterns 106a is very small.

Since the side edge 111 of the gate pattern 106a has the vertical profile, the overlap margin B between the gate pattern 106a and the active region 101 is greater than that between the conventional gate pattern having the rounded edge and the conventional active region.

Further, since the distance d between the gate patterns 106a is very small, the active region 101 will not be exposed through the gate pattern 106a, even in the case where the gate pattern 106a is laterally shifted to one side due to misalignment of a photoresist pattern or a hard mask pattern that is used for forming the gate pattern 106a. As a result, the overlap margin B of the gate pattern 106a and the active region 101 is sufficiently guaranteed so that process failures caused by exposing the active region 101 are avoided or eliminated.

Hereinafter, a method of forming a gate in FIGS. 4 and 5 in accordance with a first embodiment of the present invention is illustrated in detail with reference to accompanying drawings.

In the present embodiment, since a linear active region is required in contemporary SRAM devices having a design rule of no more than about 100 nm, the method of forming the gate that is employed in the SRAM device having the linear active region is exemplarily illustrated.

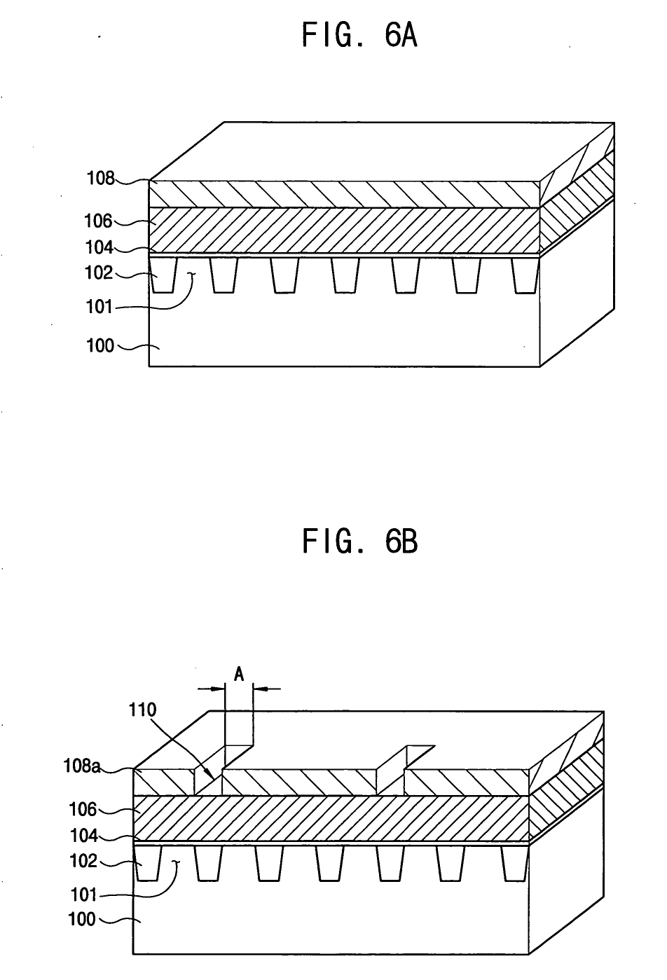

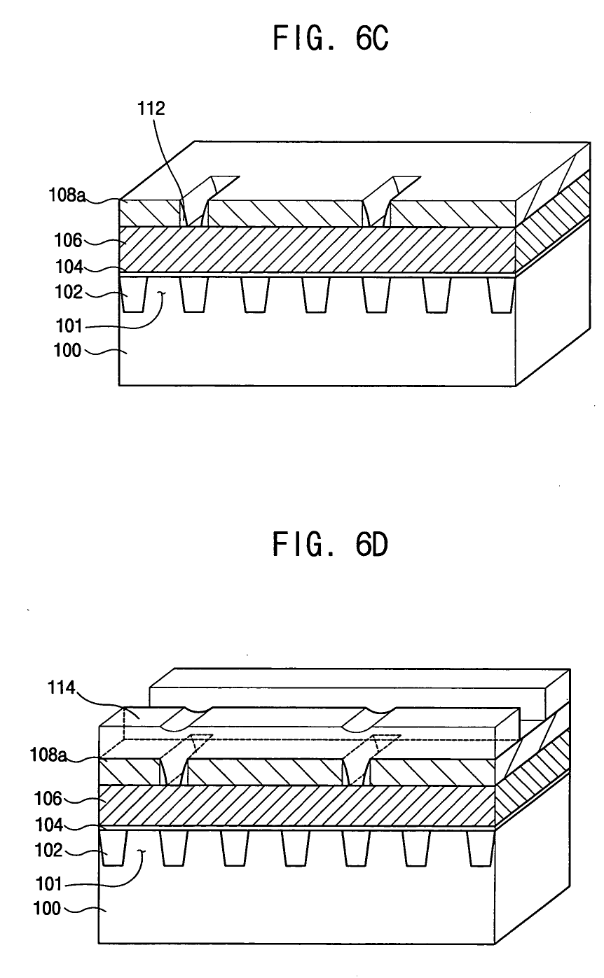

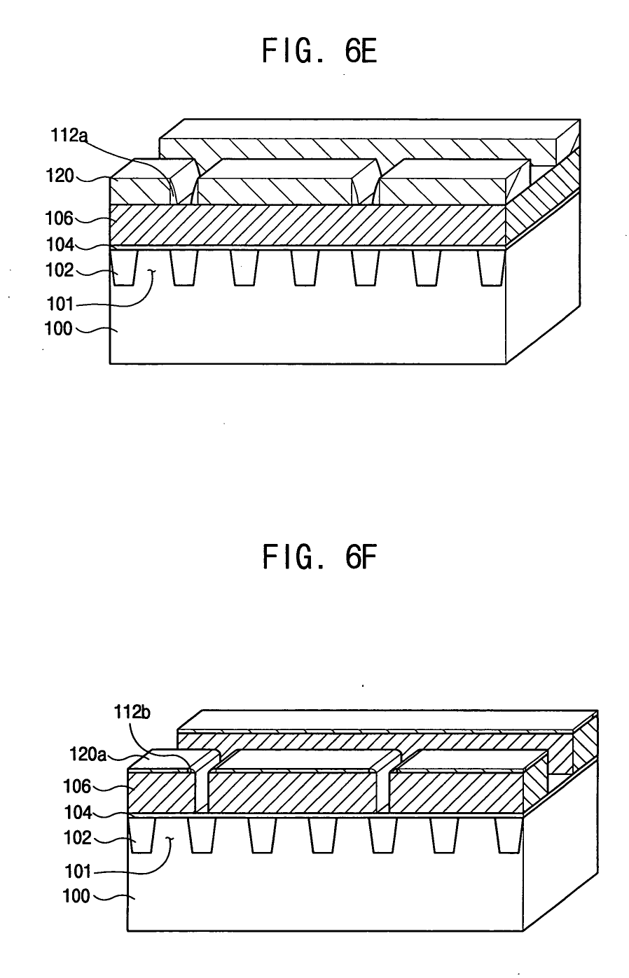

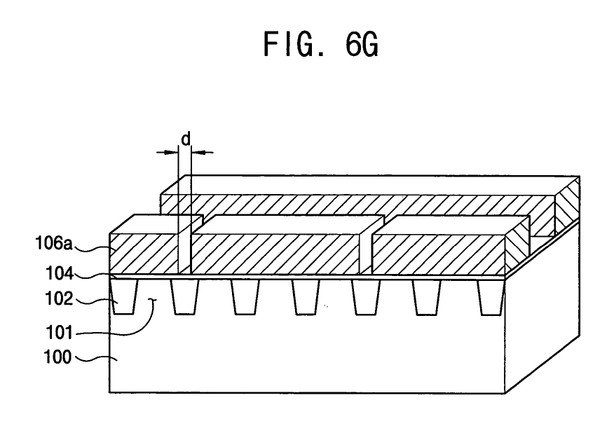

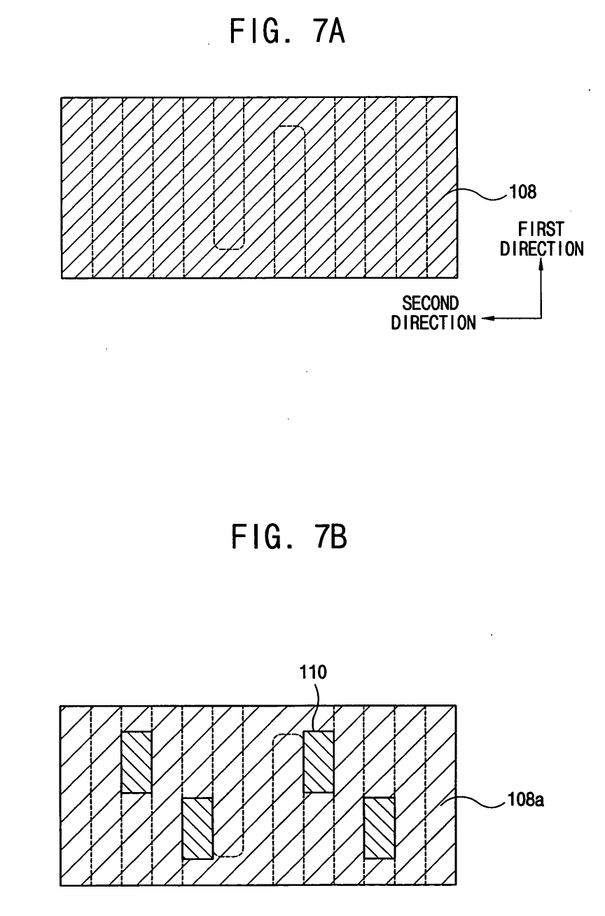

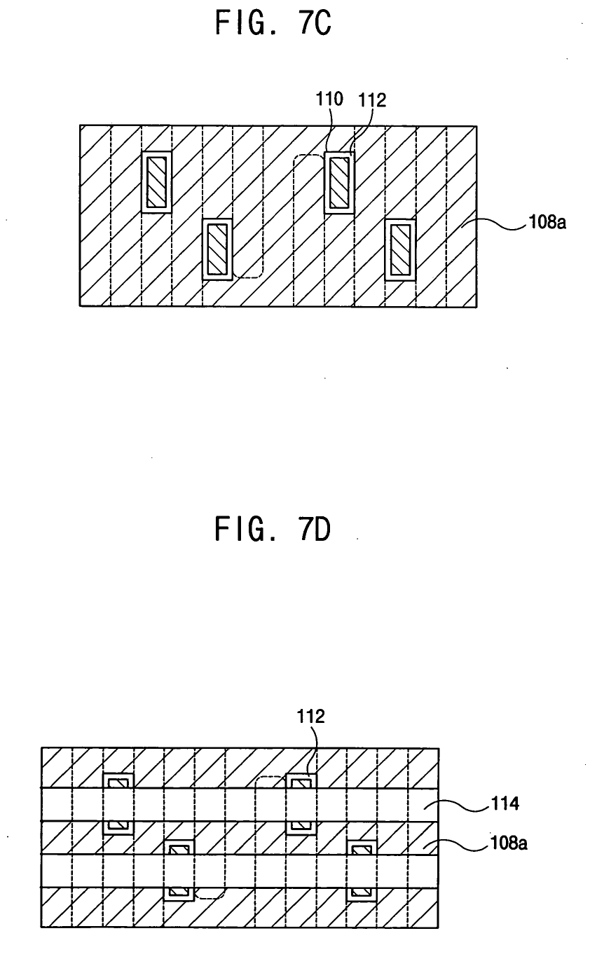

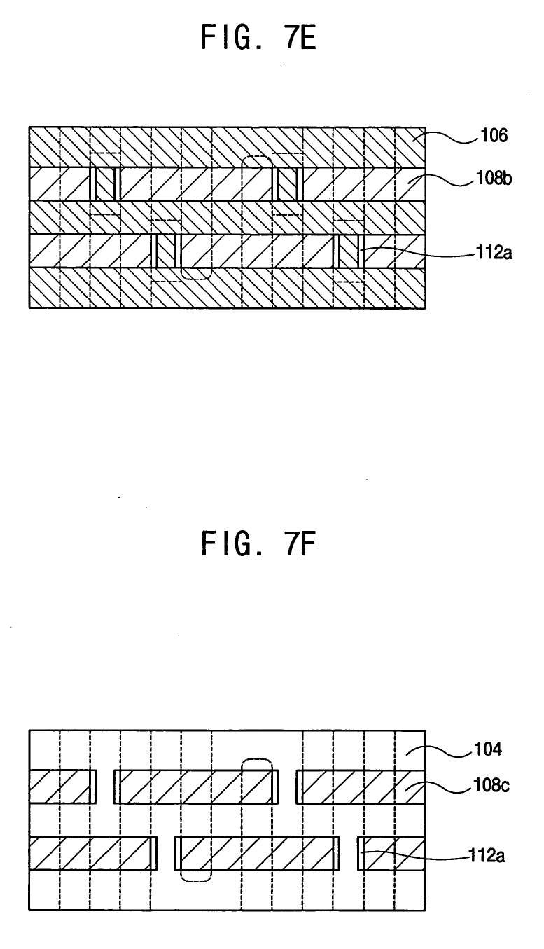

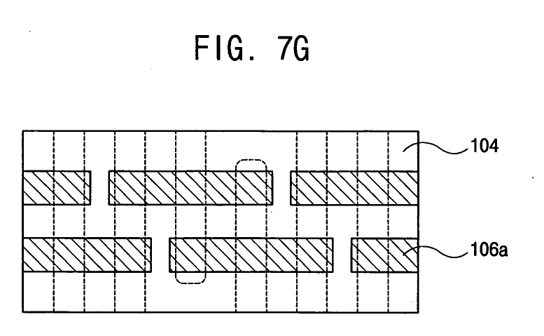

Referring to FIGS. 6A and 7A, a semiconductor substrate 100 is divided into an active region 101 and a field region 102. The active region 101 and the field region 102 extend in a first direction. The active region 101 and the field region 102 can be defined, for example, by a typical STI process. P type impurities or N type impurities are implanted into the active region 101 to form wells (not shown) of a transistor.

A gate insulating layer 104 having a thickness of no more than about 20 Å is formed on the substrate 100. The gate insulating layer 104 may include oxide. A polysilicon layer 106 having a thickness of no more than about 1,500 Å is formed on the gate insulating layer 104. A first dielectric layer 108 is formed on the polysilicon layer 106. The first dielectric layer 108 comprises, for example, a silicon nitride layer, and a silicon oxynitride layer.

Referring to FIGS. 6B and 7B, a first dielectric layer pattern 108a having an opening 110 that selectively exposes a surface of the polysilicon layer 106 is formed on the field region 102.

In particular, a photoresist film (not shown) is coated on the first dielectric layer 108. The photoresist film is selectively exposed and developed to form a first photoresist pattern (not shown) having an opening that partially exposes a surface of the first dielectric layer 108. The exposed surface of the first dielectric layer 108 is dry-etched using the first photoresist pattern as an etching mask to form the first dielectric layer pattern 108a having the opening 110 that selectively exposes the surface of the polysilicon layer 106. The first photoresist pattern is then removed by an ashing process or a stripping process.

Here, the opening 110 of the first dielectric layer pattern 108a is positioned over the field region 102. Also, the opening 110 has a width substantially equal to or less than a width A of the field region 102 in a second direction substantially perpendicular to the first direction.

Referring to FIGS. 6C and 7C, spacers 112 are formed on sidewalls of the opening 110. Particularly, a second dielectric layer (not shown) corresponding to a spacer layer is formed on the first dielectric layer pattern 108a and the exposed surface of the polysilicon layer 106. The second dielectric layer has a thickness of no more than about 200 Å, preferably about 10 Å to about 150 Å. Examples of the second dielectric layer include a silicon nitride layer, a silicon oxynitride layer, etc. The second dielectric layer is etched-back for exposing the surface of the polysilicon layer 106 in the opening 110 to form the spacers 112 on the sidewalls of the opening 110.

The spacer 112 covers the sidewalls of the opening 110 so that the width of the opening 110 is reduced, for example to a large degree. That is, the width of the opening 110 exposing the polysilicon layer 106 is narrowed by a thickness of the spacer 112 so that an exposed area of the polysilicon layer 106 through the first dielectric layer pattern 108a is likewise reduced.

Referring to FIGS. 6D and 7D, a second photoresist pattern 114 for etching the first dielectric layer pattern 108a in the second direction is formed on the first dielectric layer pattern 108a, the spacers 112 and the exposed surface of the polysilicon layer 106. To form the second photoresist pattern, a photoresist film is formed on the first dielectric layer pattern 108a, the spacers 112 and the exposed surface of the polysilicon layer 106. The photoresist film is selectively exposed and developed to form the second photoresist pattern 114. Here, the second photoresist pattern 114 has a profile substantially identical to that of the separate gate patterns 106a in FIG. 4 connected with each other.

Referring to FIGS. 6E and 7E, the exposed spacers 112 and the exposed first dielectric layer pattern 108a are etched using the second photoresist pattern 114 as an etching mask for exposing the surface of the polysilicon layer 106 to form a hard mask 120 including spacer patterns 112a. The spacer patterns 112a are used for forming a polysilicon layer pattern 106a corresponding to the gate pattern 106a in FIG. 4 that is fully overlapped with the active region 101 and includes the independent patterns. Thus, the hard mask 120 overlaps with the active region 101 and also includes the spacer pattern 112a that extending into the field region 102.

Referring to FIGS. 6F and 7F, the polysilicon layer 106 is dry-etched using the hard mask 120 including the spacer patterns 112a as an etching mask for exposing a surface of the gate insulating layer 104 to form a polysilicon layer pattern 106a. The polysilicon layer pattern 106a corresponds to the gate pattern that is overlapped with the active region 101 and also has the independent patterns. The polysilicon layer 106 is dry-etched using an etchant having an etching selectivity between the polysilicon layer 106 and the gate insulating layer 104.

Here, since the spacer patterns 112a and the hard mask 120 include silicon nitride having an etching selectivity higher than that of polysilicon, a remaining hard mask pattern 102a and a remaining spacer pattern 112b exist on the polysilicon layer pattern 106a.

Referring to FIGS. 6G and 7G, the remaining hard mask pattern 102a and the remaining spacer pattern 112b are removed to form the gate pattern 106a corresponding to the polysilicon layer pattern. The gate pattern 106a is overlapped with the active region 101, and has an end portion positioned in the field region 102 and has an edge with a vertical profile. The end portion of the gate pattern 106a has a width substantially identical to the thickness of the spacer pattern 112.

The gate patterns 106a can serve as a gate electrode of the PMOS transistor or the NMOS transistor. Also, the distance d between the gate patterns 106a is relatively very short, as compared the conventional gate patterns. Thus, in a case where the gate pattern 106 is caused to inaccurately overlap with the active region 101 due to lateral shifting of the photo-patterns for forming the gate region, the overlapped region between the end of the gate pattern 106a and the active region can be sufficiently guaranteed due to the linear profile of the edge of the gate pattern.

### Embodiment 2

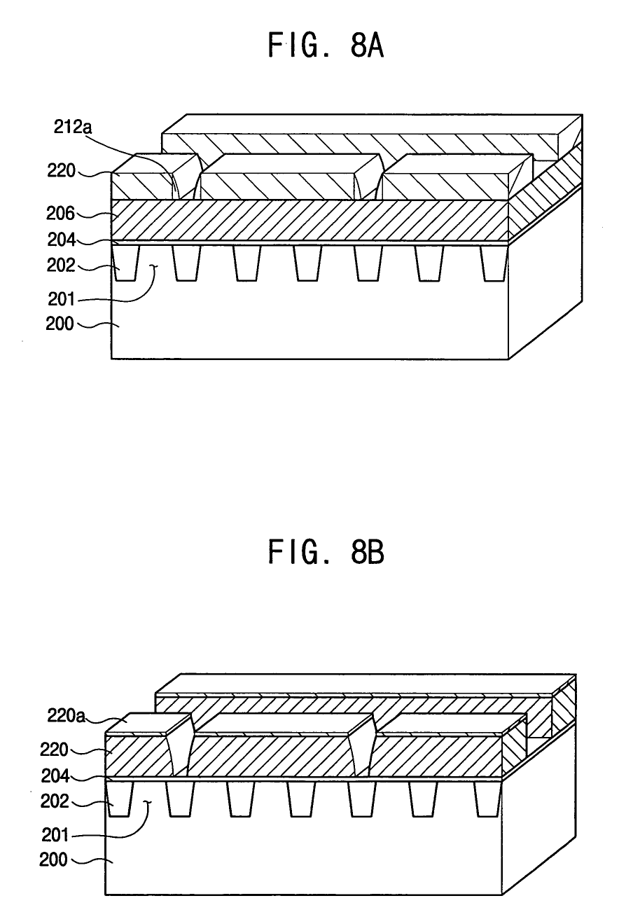

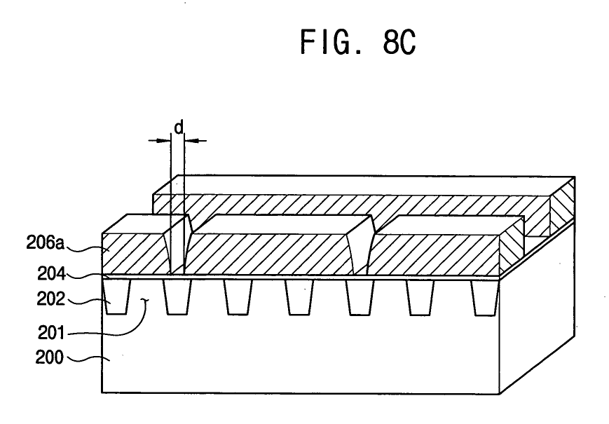

Referring to FIG. 8A, a method of forming a gate in accordance with a second embodiment of the present invention is substantially identical to that in accordance with Embodiment 1 except that a spacer pattern 212a includes polysilicon in place of silicon nitride in Embodiment 1. Thus, since a process for forming a hard mask 220 is illustrated in detail in Embodiment 1, further detailed explanation of the process for forming the hard mask 220 is omitted.

Referring to FIG. 8B, a polysilicon layer 206 is dry-etched using the hard mask 220 as an etching mask for exposing a surface of a gate insulating layer 204 to form a polysilicon layer pattern 206a. The polysilicon layer pattern 206a corresponds to a gate pattern that is overlapped with an active region 201 and also has independent patterns having a trapezoidal-shaped profile.

Here, since the hard mask 220 includes silicon nitride having an etching selectivity higher than that of polysilicon and since the spacer pattern 212a includes polysilicon having an etching selectivity substantially identical to that of polysilicon, only a remaining hard mask pattern 220a exists on the polysilicon layer pattern 206a.

Further, since the spacer pattern 212a is removed before forming the polysilicon layer pattern 206a, the polysilicon layer pattern 206a has the trapezoidal shaped profile that has bottom side edges that are wider relative to the upper side edges.

Referring to FIG. 8C, the remaining hard mask pattern 220a is removed to form a gate pattern 206a corresponding to the polysilicon layer pattern. Thus, the gate pattern 206a is overlapped with the active region 201, and also has the independent patterns having the trapezoidal shape and also a vertical profile.

The gate pattern 206a may serve as a gate electrode of the PMOS transistor or the NMOS transistor. Also, the distance d between the gate patterns 206a is relatively short, whereas an upper width of a trench formed between the gate patterns 206a is wider than the distance d. Thus, when an insulating interlayer (not shown) is formed in the trench, voids are not formed in the insulating interlayer.

According to the present invention, although the gate pattern is laterally shifted to one side due to mis-alignment of the photoresist pattern or the hard mask, the distance between the gate patterns is relatively very short so that the active region is not exposed. As a result, the overlap margin between the gate pattern and the active region is sufficiently guaranteed to prevent malfunction of a transistor due to insufficient overlap margin.

Also, since the gate pattern has the trapezoidal curved profile, the distance between the gate patterns is very short and the upper width of the trench formed between the gate patterns is wider than the distance. Thus, when an insulating interlayer is formed in the trench, voids are not formed in the insulating interlayer.

While this invention has been particularly shown and described with references to preferred embodiments thereof, it will be understood by those skilled in the art that various changes in form and details may be made herein without departing from the spirit and scope of the invention as defined by the appended claims.

1. A method of forming a gate of a semiconductor device comprising:
successively forming a gate insulating layer and a polysilicon layer on a substrate that is partitioned into an active region and a field region;
forming a hard mask on the polysilicon layer, the hard mask overlapping the active region and the hard mask including a spacer pattern that partially extends into the field region; and
partially etching the polysilicon layer using the hard mask as an etching mask to form the gate that overlaps the active region and that has an end portion positioned on the field region, the end portion having a width at least as large as a thickness of the spacer pattern.

2. The method of claim 1, wherein forming the hard mask comprises:
forming a dielectric layer on the polysilicon layer;
patterning the dielectric layer to form a dielectric layer pattern having an opening selectively exposing the polysilicon layer in the field region;
forming a spacer on an inner sidewall of the opening of the dielectric layer pattern;
forming a photoresist pattern on the dielectric layer pattern having the spacer; and
etching the dielectric layer pattern and the spacer using the photoresist pattern as an etching mask to form the hard mask.

3. The method of claim 1, wherein the spacer pattern comprises silicon nitride, silicon oxynitride or polysilicon.

4. The method of claim 1, wherein the hard mask comprises silicon nitride or silicon oxynitride.

5. The method of claim 1, wherein the active region and the field region extend in a first direction, and wherein the gate extends in a second direction substantially perpendicular to the first direction.

6. The method of claim 1, wherein the polysilicon layer is etched using an etchant having an etching selectivity between the polysilicon layer and the gate insulating layer.

7. The method of claim 1, wherein the gate has a length of no more than about 100 nm.

8. A method of forming a gate of a semiconductor device comprising:
successively forming a gate insulating layer and a polysilicon layer on a substrate that is partitioned into an active region and a field region, the active region and the field region extending in a first direction;
forming a dielectric layer pattern on the polysilicon layer, the dielectric layer pattern having an opening that selectively exposes a surface of the polysilicon layer in the field region;
forming a spacer on an inner sidewall of the opening of the dielectric pattern;
partially etching the dielectric layer having the spacer to form a hard mask on the polysilicon layer, the hard mask overlapping with the active region and the hard mask including a spacer pattern that partially extends into the field region; and
partially etching the polysilicon layer using the hard mask as an etching mask to form the gate that overlaps with the active region and that has an end portion positioned on the field region, the end portion having a width at least as large as a thickness of the spacer pattern, the gate extending in a second direction.

9. The method of claim 7, wherein forming the spacer comprises:
forming a spacer layer having a thickness of about 10 Å to about 150 Å on exposed surfaces of the dielectric layer pattern and the polysilicon layer; and
etching the spacer layer to form the spacer.

10. The method of claim 9, wherein the spacer layer comprises silicon nitride, silicon oxynitride or polysilicon.

11. The method of claim 8, wherein the hard mask comprises silicon nitride or silicon oxynitride.

12. The method of claim 8, wherein forming the hard mask comprises:
forming a photoresist pattern in the second direction on the dielectric layer pattern having the spacer; and
etching the dielectric layer pattern and the spacer using the photoresist pattern as an etching mask to form the hard mask.

13. The method of claim 8, wherein the polysilicon layer is etched using an etchant having an etching selectivity between the polysilicon layer and the gate insulating layer.

14. The method of claim 8, wherein the first direction is substantially perpendicular to the second direction.
